(19) United States
(12) Patent Application Publication
(10) Pub. No.: US 2011/0278619 A1
(43) Pub. Date: Nov. 17, 2011

(54) QUATERNARY VERTICAL LIGHT EMITTING DIODE WITH DOUBLE SURFACE ROUGHENING AND MANUFACTURING METHOD THEREOF

(75) Inventors: XIAOXIONG LIN, XIAMEN CITY (CN); CHIAHAO TSAI, XIAMEN (CN); SUHUI LIN, XIAMEN CITY (CN); LINGFENG YIN, XIAMEN CITY (CN); KECHUANG LIN, XIAMEN CITY (CN)

(73) Assignee: XIAMEN SANAN OPTOELECTRONICS TECHNOLOGY CO., LTD., XIAMEN CITY (CN)

(21) Appl. No.: 13/107,537

(22) Filed: May 13, 2011

(30) Foreign Application Priority Data
May 14, 2010 (CN) 201010181217.9

(51) Int. Cl. H01L 33/10; H01L 33/60

(52) U.S. Cl. 257/98; 438/29; 257/E33.072; 257/E33.074

(57) ABSTRACT

The present invention discloses a quaternary vertical light emitting diode with double surface roughening and a manufacturing method thereof, where a Bragg reflective layer is formed on a substrate; a first type of epitaxial layer is formed on the Bragg reflective layer; a light emitting layer is formed on the first type of epitaxial layer; a second type of epitaxial layer is formed on the light emitting layer; a first GaP window layer with small circular holes or in a mesh structure is formed on the second type of epitaxial layer; a second GaP window layer with small circular holes or in a mesh structure is formed on the first GaP window layer; a first electrode is formed on the top surface of the second GaP window layer; and a second electrode is formed on the bottom surface of the GaAs substrate. After conventional processes, the invention forms the alternating small circular holes or the mesh structure between the first GaP window layer and the second GaP window layer to change a light path along which light emitting from the light emitting layer reaches the surface of a light emitting diode die so that more of light emits from inside and the light extracting rate of the invention is 20% higher than that of an existing light emitting diode.

### FIELD OF THE INVENTION

The present invention relates to a quaternary light emitting diode and in particular to a quaternary vertical light emitting diode with double surface roughening and a manufacturing method thereof.

### BACKGROUND OF THE INVENTION

At present, light emitting diodes have been applied widely in economic life, for example, display, decoration, communication, etc., and their general structure typically includes a substrate, a distributed Bragg reflective layer, a first type of epitaxial layer, a light emitting layer, a second type of epitaxial layer, a window layer, a first electrode and a second electrode. The window layer of an existing vertically structured quaternary AlGaInP light emitting diode is typically structured as a single GaP layer with a planar upper surface, so when the light emitting layer acting as an interlayer emits light, a part of light emits towards the outside of the element and most of light may be subject to total reflection to thereby result in a poor emergence effect of light. Due to a semiconductor material which is a material with a high refractive index relative to the ambient air, total reflection will be caused when a emergence angle of light is larger than a certain critical angle; and also totally reflected light may generate heat inside the light emitting diode so that the overall temperature of the light emitting diode will rise, thus greatly degrading the reliability of the product.

In order to alleviate the problem of most of light being totally reflected due to the significant difference between high and low refractive indexes, some researchers have proposed the use of a P-GaN surface roughening method to rough the interface regularly so that part of totally reflected light can emerge in the form of scattered light to thereby improve the light extracting rate, but direct roughening of the top surface of an LED may cause some damage to an active layer and a transparent electrode and also render the LED difficult to manufacture.

### SUMMARY OF THE INVENTION

In order to address the foregoing problem, the invention is intended to provide a quaternary vertical light emitting diode with double surface roughening and a manufacturing method thereof

In a technical solution adopted according to the invention to address the technical problem thereof, a quaternary vertical light emitting diode with double surface roughening includes: a Bragg reflective layer formed on a substrate; a first type of epitaxial layer formed on the Bragg reflective layer; a light emitting layer formed on the first type of epitaxial layer; a second type of epitaxial layer formed on the light emitting layer; a first GaP window layer with small circular holes or in a mesh structure formed on the second type of epitaxial layer; a second GaP window layer with small circular holes or in a mesh structure formed on the first GaP window layer; a first electrode formed on the top surface of the second GaP window layer; and a second electrode formed on the bottom surface of the substrate.

A method for manufacturing a quaternary vertical light emitting diode with double surface roughening includes the steps of:

1) growing epitaxially and forming a distributed Bragg reflective layer, a first type of epitaxial layer, a light emitting layer and a second type of epitaxial layer on a substrate sequentially;

2) forming a first GaP window layer on the second type of epitaxial layer;

3) forming a mesh structure consisted of patterns of small circular holes or channels in the first GaP window layer by a wet or dry etch method;

4) forming a second GaP window layer on the first GaP window;

5) forming a mesh structure consisted of patterns of small circular holes or channels in the second GaP window layer by a wet or dry etch method to arrange the patterns of the first GaP window layer and the second GaP window layer alternately without overlapping;

6) forming a first electrode on the top surface of the second GaP window layer and a second electrode on the bottom surface of the substrate; and

7) dicing the substrate into quaternary vertical light emitting diodes.

According to the invention, the material of the substrate is selected from any one or combination of GaAs and GaP; the thickness of the first GaP window layer ranges from 1 to 3 μm, wherein the diameter of the small circular holes or the width of the channels in the mesh structure ranges from 2 to 4 μm, and the small circular holes or the channels are spaced at an interval ranging from 3 to 5 μm; the thickness of the second GaP window layer ranges from 5 to 7 μm, wherein the diameter of the small circular holes or the width of the channels in the mesh structure ranges from 2 to 4 μm, and the small circular holes or the channels are spaced at an interval ranging from 3 to 5 μm; an etching solution for the wet etch method is selected from any one or combination of HF, NH₄F, CH₃COOH, H₂SO₄ and H₂O₂; and an etching gas for the dry etch method is selected from any one or combination of Ar₂, O₂, BCl₃, Cl₂ and SiCl₄.

As compared with the prior art, after conventional processes, the invention forms the alternating small circular holes or the mesh structure between the first GaP window layer and the second GaP window layer to change a light path along which light emitting from the light emitting layer reaches the surface of a light emitting diode die so that more of light is extracted from inside and the light extracting rate of the light emitting diode is 20% higher than in the prior art.

### BRIEF DESCRIPTION OF THE DRAWINGS

FIG. 1 is a schematic sectional view of a quaternary vertical light emitting diode with double surface roughening according to the invention.

FIG. 2 is a top view of the quaternary vertical light emitting diode with double surface roughening according to the invention.

Reference numerals in the drawings are listed as follows:

| | |
|---|---|
| 1. Substrate | 2. Bragg reflective layer |
| 3. First type of epitaxial layer | 4. Light emitting layer |
| 5. Second type of epitaxial layer | 6. First GaP window layer |
| 7. Second GaP window layer | 8. First electrode |
| 9. Second electrode | |

### DETAILED DESCRIPTION OF THE INVENTION

The invention will be further described hereinafter with reference to the drawings and embodiments thereof.

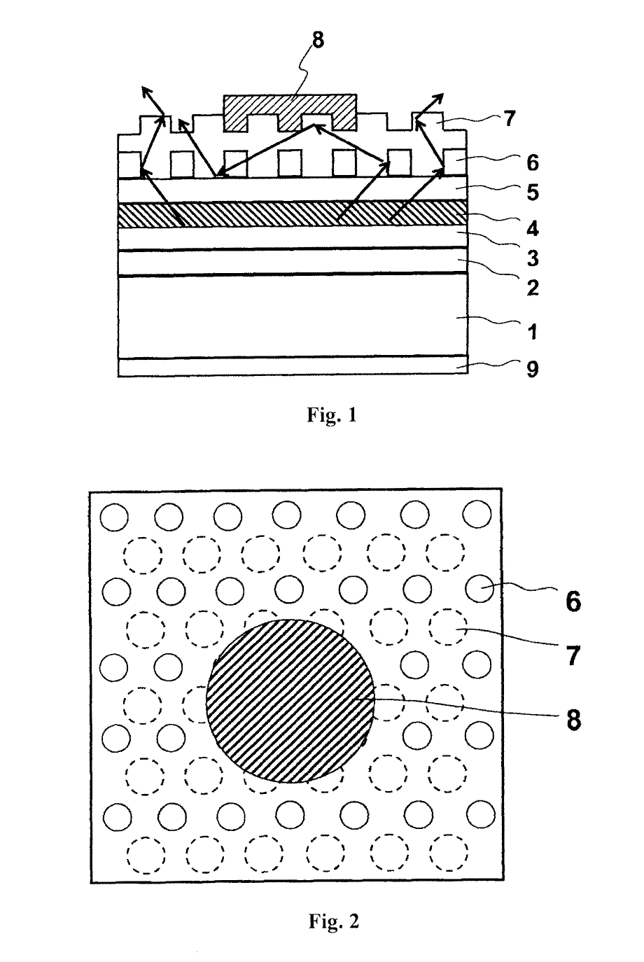

As illustrated in FIG. 1, in a method for manufacturing a quaternary vertical light emitting diode with double surface roughening, a process of manufacturing the same includes the following steps:

A distributed Bragg reflective layer 2, a first type of epitaxial layer 3, a light emitting layer 4 and a second type of epitaxial layer 5 are grown epitaxially and formed on a GaAs substrate 1 sequentially.

A first GaP window layer 6 is formed on the second type of epitaxial layer 5, wherein a thickness of the first window layer 6 is 2 μm.

The first GaP window layer 6 is etched in a wet etch method with an etching solution consisted of HF, NH₄F, CH₃COOH, H₂SO₄ and H₂O₂ to form therein a mesh structure consisted of small circular holes, wherein a diameter of the small circular hole is 4 μm and the small circular holes are spaced at an interval of 3 μm.

A second GaP window 7 with a thickness of 6 μm is formed on the first GaP window layer 6.

The second GaP window layer 7 is etched in a dry etch method with an etching gas consisted of Ar₂, O₂, BCl₃, Cl₂ and SiCl₄ to form therein a mesh structure consisted of small circular holes so as to arrange patterns of the first GaP window 6 and the second GaP window 7 alternately without overlapping wherein a diameter of the small circular hole is 3 μm and the small circular holes are spaced at an interval of 4 μm.

A first electrode 8 is formed on the top surface of the second GaP window 7, and a second electrode 9 is formed on the bottom surface of the substrate 1.

The substrate is diced into quaternary vertical light emitting diodes.

As illustrated in FIG. 1, a quaternary vertical light emitting diode with double surface roughening manufactured according to the above method includes: a GaAs substrate 1; a distributed Bragg reflective layer 2 formed on the GaAs substrate 1; a first type of epitaxial layer 3 formed on the distributed Bragg reflective layer 2; a light emitting layer 4 formed on the first type of epitaxial layer 3; a second type of epitaxial layer 5 formed on the light emitting layer 4; a first GaP window layer 6 in a mesh structure consisted of small circular holes formed on the second type of epitaxial layer 5; a second GaP window layer 7 in a mesh structure consisted of small circular holes formed on the first GaP window layer 6; a first electrode 8 formed on the top surface of the second GaP window layer 7; and a second electrode 9 formed on the bottom surface of the GaAs substrate 1.

As can be apparent from FIG. 1 and FIG. 2, light emitting from the light emitting layer 4 firstly passes the interface between the first GaP window layer 6 and the second GaP window layer 7 to be scattered due to the mesh structure consisted of the small circular holes on the first GaP window layer 6, and thereafter light passes the interface between the second GaP window layer 7 and the air to be scattered again due to the mesh structure consisted of the small circular holes on the second GaP window layer 7, thereby greatly improving the light extracting rate of the light emitting diode.

The foregoing embodiments are provided to merely illustrate but not limit the invention, and those ordinarily skilled in the art can further make various modifications or variations without departing from the spirit and scope of the invention. Accordingly all equivalent technical solutions come to the scope of the invention as defined in the appended claims.

1. A quaternary vertical light emitting diode with double surface roughening, comprising: a Bragg reflective layer formed on a substrate; a first type of epitaxial layer formed on the Bragg reflective layer; a light emitting layer formed on the first type of epitaxial layer; a second type of epitaxial layer formed on the light emitting layer; a first GaP window layer with small circular holes or in a mesh structure formed on the second type of epitaxial layer; a second GaP window layer with small circular holes or in a mesh structure formed on the first GaP window layer; a first electrode formed on the top surface of the second GaP window layer; and a second electrode formed on the bottom surface of the GaAs substrate.

2. The quaternary vertical light emitting diode with double surface roughening according to claim 1, wherein the thickness of the first GaP window layer ranges from 1 to 3 μm, wherein in the first Gap window layer, the diameter of the small circular holes or the width of the channels in the mesh structure ranges from 2 to 4 μm, and the small circular holes or the channels are spaced at an interval ranging from 3 to 5 μm.

3. The quaternary vertical light emitting diode with double surface roughening according to claim 1, wherein the thickness of the second GaP window layer ranges from 5 to 7 μm, wherein in the second GaP window, the diameter of the small circular holes or the width of the channels in the mesh structure ranges from 2 to 4 μm, and the small circular holes or the channels are spaced at an interval ranging from 3 to 5 μm.

4. A method for manufacturing a quaternary vertical light emitting diode with double surface roughening, comprising the steps of:
1) growing epitaxially and forming a distributed Bragg reflective layer, a first type of epitaxial layer, a light emitting layer and a second type of epitaxial layer on a substrate sequentially;
2) forming a first GaP window layer on the second type of epitaxial layer;
3) forming a mesh structure consisted of patterns of small circular holes or channels in the first GaP window layer by a wet or dry etch method;
4) forming a second GaP window layer on the first GaP window;
5) forming a mesh structure consisted of patterns of small circular holes or channels in the second GaP window layer by a wet or dry etch method to arrange the patterns of the first GaP window layer and the second GaP window layer alternately without overlapping;
6) forming a first electrode on the top surface of the second GaP window layer and a second electrode on the bottom surface of the substrate; and
7) dicing into quaternary vertical light emitting diodes.

5. The method for manufacturing a quaternary vertical light emitting diode with double surface roughening according to claim 4, wherein the material of the substrate is selected from any one or combination of GaAs and GaP.

6. The method for manufacturing a quaternary vertical light emitting diode with double surface roughening according to claim 4, wherein the thickness of the first GaP window layer ranges from 1 to 3 μm, wherein in the first Gap window layer, the diameter of the small circular holes or the width of the channels in the mesh structure ranges from 2 to 4 μm, and the small circular holes or the channels are spaced at an interval ranging from 3 to 5 μm.

7. The method for manufacturing a quaternary vertical light emitting diode with double surface roughening according to claim 4, wherein the thickness of the second GaP window layer ranges from 5 to 7 μm, wherein in the second GaP window, the diameter of the small circular holes or the width of the channels in the mesh structure ranges from 2 to 4 μm, and the small circular holes or the channels are spaced at an interval ranging from 3 to 5 μm.

8. The method for manufacturing a quaternary vertical light emitting diode with double surface roughening according to claim 4, wherein an etching solution for the wet etch method is selected from any one or combination of HF, NH₄F, CH₃COOH, H₂SO₄ and H₂O₂.

9. The method for manufacturing a quaternary vertical light emitting diode with double surface roughening according to claim 4, wherein an etching gas for the dry etch method is selected from any one or combination of Ar₂, O₂, BCl₃, Cl₂ and SiCl₄.
